(19) United States
(12) Patent Application Publication
(10) Pub. No.: US 2024/0042753 A1
(43) Pub. Date: Feb. 8, 2024

(54) SUBSTRATE TREATMENT APPARATUS AND METHOD

(71) Applicant: SEMES CO., LTD., Chungcheongnam-do (KR)

(72) Inventors: Jeong Ho JO, Chungcheongnam-do (KR); Ji Eun YI, Chungcheongnam-do (KR)

(21) Appl. No.: 18/228,665

(22) Filed: Jul. 31, 2023

(30) Foreign Application Priority Data
Aug. 2, 2022 (KR) 10-2022-0096284

(51) Int. Cl. B41J 2/045; B41J 2/21

(52) U.S. Cl. CPC B41J 2/0451; B41J 2/2142

(57) ABSTRACT

Provided are a substrate treatment apparatus and method which reconstruct a compensation nozzle map by processing nozzles in a specific area among all nozzles as unused nozzles. The substrate treatment apparatus includes: a process processing unit supporting a substrate while the substrate is being treated; an inkjet head unit including a plurality of nozzles and jetting a substrate treatment liquid onto the substrate to treat the substrate; a gantry unit moving the inkjet head unit on the substrate; and a controller controlling the nozzles, wherein the controller compensates for an abnormal nozzle by not using normal nozzles.

This application claims the benefit of Korean Patent Application No. 10-2022-0096284, filed on Aug. 2, 2022, in the Korean Intellectual Property Office, the disclosure of which is incorporated herein in its entirety by reference.

### BACKGROUND

### 1. Field

The present disclosure relates to a substrate treatment apparatus and method, and more particularly, to a substrate treatment apparatus and method applied to a process of manufacturing a semiconductor device or a display device.

### 2. Description of the Related Art

When a display device such as an LCD panel or an LED panel is manufactured, a printing process may be performed on a transparent substrate using inkjet equipment. The inkjet equipment may perform a patterning process (e.g., RGB patterning) at a desired location by jetting fine ink droplets onto the transparent substrate using an inkjet head.

Area inkjet equipment usually performs printing using a two-scan method and compensates for a non-jetting nozzle. However, if non-jetting occurs again in the same nozzle, the printing method is changed to a three-scan method to compensate for the non-jetting nozzle. However, when the number of scans is increased, the tact time of the entire equipment may increase.

### SUMMARY

Aspects of the present disclosure provide a substrate treatment apparatus and method which reconstruct a compensation nozzle map by processing nozzles in a specific area among all nozzles as unused nozzles.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a substrate treatment apparatus including: a process processing unit supporting a substrate while the substrate is being treated; an inkjet head unit including a plurality of nozzles and jetting a substrate treatment liquid onto the substrate to treat the substrate; a gantry unit moving the inkjet head unit on the substrate; and a controller controlling the nozzles, wherein the controller compensates for an abnormal nozzle by not using normal nozzles.

According to another aspect of the present disclosure, there is provided a substrate treatment apparatus including: a process processing unit supporting a substrate while the substrate is being treated; an inkjet head unit including a plurality of nozzles and jetting a substrate treatment liquid onto the substrate to treat the substrate; a gantry unit moving the inkjet head unit on the substrate; and a controller controlling the nozzles, wherein the controller compensates for an abnormal nozzle by not using normal nozzles when a jetting position of the abnormal nozzle is the same in substrate printing for each of successive swaths, the controller processes a plurality of nozzles located first in a jetting order among the nozzles as unused nozzles, processes a plurality of nozzles located last as unused nozzles, or processes a nozzle located first and a nozzle located last as unused nozzles, the controller compensates for the abnormal nozzle by shifting all nozzles except for the unused nozzles, and the controller determines the number of unused normal nozzles according to the number of abnormal nozzles.

According to another aspect of the present disclosure, there is provided a substrate treatment method including: determining whether there is an abnormal nozzle among a plurality of nozzles; identifying the position and number of abnormal nozzles if it is determined that there is the abnormal nozzle; processing some of normal nozzles as unused nozzles; compensating for the abnormal nozzle using all nozzles except for the unused nozzles; and printing a substrate using the all nozzles whose jetting positions have been adjusted.

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view schematically illustrating the structure of a substrate treatment apparatus according to an embodiment of the present disclosure;

FIG. 2 is an example view for explaining a method of operating the substrate treatment apparatus according to the embodiment of the present disclosure;

FIG. 3 is an example view illustrating an operation of jetting a substrate treatment liquid onto a substrate by moving an inkjet head unit forward for substrate printing;

FIG. 4 is an example view illustrating an operation of jetting the substrate treatment liquid onto the substrate by moving the inkjet head unit backward for substrate printing;

FIG. 5 is a first example view for explaining a non-jetting nozzle compensation method of a controller constituting the substrate treatment apparatus;

FIG. 6 is a first example view for explaining an unused nozzle determination method of the controller constituting the substrate treatment apparatus;

FIG. 7 is a second example view for explaining an unused nozzle determination method of the controller constituting the substrate treatment apparatus;

FIG. 8 is a third example view for explaining an unused nozzle determination method of the controller constituting the substrate treatment apparatus;

FIG. 9 is a fourth example view for explaining an unused nozzle determination method of the controller constituting the substrate treatment apparatus;

FIG. 10 is a second example view for explaining a non-jetting nozzle compensation method of the controller constituting the substrate treatment apparatus;

FIG. 11 is a third example view for explaining a non-jetting nozzle compensation method of the controller constituting the substrate treatment apparatus;

FIG. 12 is a fourth example view for explaining a non-jetting nozzle compensation method of the controller constituting the substrate treatment apparatus; and

FIG. 13 is a flowchart sequentially illustrating a method of operating the controller constituting the substrate treatment apparatus.

### DETAILED DESCRIPTION

Hereinafter, embodiments of the present disclosure will be described in detail with reference to the attached drawings. Like elements in the drawings will be indicated by like reference numerals, and a redundant description thereof will be omitted.

The present disclosure relates to a substrate treatment apparatus and method for jetting a substrate treatment liquid (e.g., ink) onto a substrate using an inkjet head unit. The present disclosure is characterized in that a compensation nozzle map is reconstructed by processing nozzles in a specific area as unused nozzles among a plurality of nozzles installed in the inkjet head unit. According to the present disclosure, it is not necessary to increase the number of scans even if non-jetting nozzles overlap, and the effect of preventing an increase in tact time of the entire equipment can be obtained. Hereinafter, the present disclosure will be described in detail with reference to drawings and the like.

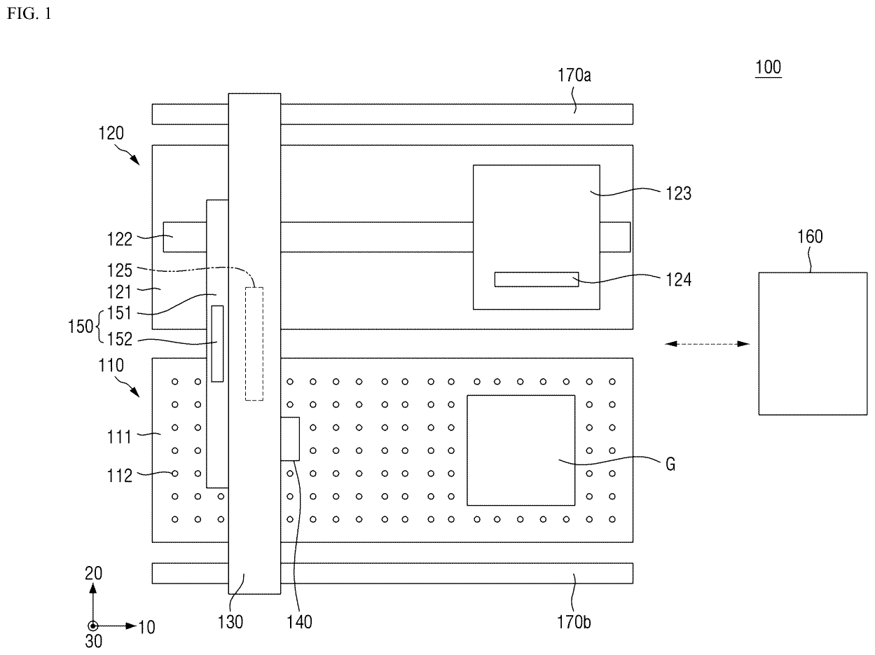

FIG. 1 is a plan view schematically illustrating the structure of a substrate treatment apparatus 100 according to an embodiment of the present disclosure.

Referring to FIG. 1, the substrate treatment apparatus 100 may include a process processing unit 110, a maintenance unit 120, a gantry unit 130, an inkjet head unit 140, a substrate treatment liquid providing unit 150, and a controller 160.

The substrate treatment apparatus 100 treats a substrate G (e.g., a glass substrate) used to manufacture a semiconductor device or a display device. The substrate treatment apparatus 100 may be provided as inkjet equipment that performs a printing process on the substrate G by jetting a substrate treatment liquid onto the substrate G using the inkjet head unit 140.

The substrate treatment apparatus 100 may use ink as the substrate treatment liquid. Here, the substrate treatment liquid refers to a chemical liquid used to print the substrate G. The substrate treatment liquid may be, for example, quantum dot (QD) ink containing ultra-fine semiconductor particles, and the substrate treatment apparatus 100 may be provided as, for example, inkjet equipment that forms a color filter on the substrate G by using the QD ink. The substrate treatment apparatus 100 may perform pixel printing on the substrate G by using the substrate treatment liquid and may be provided as circulating inkjet equipment to prevent nozzles from being clogged by the substrate treatment liquid.

The process processing unit 110 supports the substrate G while a PT operation is performed on the substrate G. Here, the PT operation refers to an operation of printing the substrate G using the substrate treatment liquid.

The process processing unit 110 may support the substrate G in a contactless manner. The process processing unit 110 may be provided as, for example, an air floating unit that supports the substrate G by floating the substrate G in the air using air.

However, the current embodiment is not limited thereto. The process processing unit 110 may also support the substrate G in a contact manner. The process processing unit 110 may be provided as, for example, a chuck unit that supports the substrate G while adsorbing the substrate G thereto.

The process processing unit 110 may move the substrate G while supporting the substrate G using air. The process processing unit 110 may include, for example, a first stage 111 and an air holes 112.

The first stage 111 is a base and is provided so that the substrate G can be mounted thereon. The air holes 112 may be formed to penetrate an upper surface of the first stage 111 and may be formed in a printing zone on the first stage 111.

The air holes 112 may spray air in an upward direction (third direction 30) of the first stage 111. Accordingly, the air holes 112 may float the substrate G mounted on the first stage 111 in the air.

Although not illustrated in FIG. 1, the process processing unit 110 may further include a gripper and a guide rail. When the substrate G moves along a longitudinal direction (first direction 10) of the first stage 111, the gripper grips the substrate G to prevent separation of the substrate G from the first stage 111. When the substrate G moves, the gripper may move in the same direction as the substrate G along the guide rail while gripping the substrate G. The gripper and the guide rail may be provided outside the first stage 111.

When the process processing unit 110 is provided as a chuck unit, it may move the substrate G by moving a chuck forward, backward, to the left, or to the right.

The maintenance unit 120 measures a jetting position (i.e., target point) of the substrate treatment liquid on the substrate G, whether to jet the substrate treatment liquid, and the like. The maintenance unit 120 may measure the jetting position of the substrate treatment liquid, whether to jet the substrate treatment liquid, and the like for each of a plurality of nozzles provided in the inkjet head unit 140, and the measurement results thus obtained may be provided to the controller 160.

The maintenance unit 120 may include, for example, a second stage 121, a third guide rail 122, a first plate 123, a calibration board 124, and a vision module 125.

The second stage 121 is a base, like the first stage 111, and may be disposed parallel to the first stage 111. The second stage 121 may include a maintenance zone thereon. The second stage 121 may have the same size as the first stage 111, but may also have a smaller or larger size than the first stage 111.

The third guide rail 122 guides the movement path of the first plate 123. The third guide rail 122 may be provided as at least one line on the second stage 121 along the longitudinal direction (first direction 10) of the second stage 121. The third guide rail 122 may be implemented as, for example, a linear motor guide system.

Although not illustrated in FIG. 1, the maintenance unit 120 may further include a fourth guide rail. Like the third guide rail 122, the fourth guide rail guides the movement path of the first plate 123 and may be provided as at least one line on the second stage 121 along a width direction (second direction 20) of the second stage 121.

The first plate 123 moves on the second stage 121 along the third guide rail 122 and/or the fourth guide rail. The first plate 123 may move parallel to the substrate G along the third guide rail 122 and may approach or move away from the substrate G along the fourth guide rail.

The calibration board 124 is designed to measure the jetting position of the substrate treatment liquid on the substrate G. The calibration board 124 may include an align mark, a ruler, etc. and may be installed on the first plate 123. The calibration board 124 may be provided along the longitudinal direction (first direction 10) of the first plate 123.

The vision module 125 includes a camera module and obtains image information of the substrate G. The image information of the substrate G obtained by the vision module 125 may include information about whether the substrate treatment liquid has been jetted, the position of the substrate treatment liquid jetted, the amount of the substrate treatment liquid jetted, and the area of the substrate treatment liquid jetted. The vision module 125 may obtain and provide information about the calibration board 124 in addition to the image information of the substrate G onto which the substrate treatment liquid has been jetted.

The vision module 125 may obtain the image information of the substrate G in real time while the substrate G is treated. The vision module 125 may obtain the image information by photographing the substrate G in the longitudinal direction (first direction 10). In this case, the vision module 125 may include a line scan camera. In addition, the vision module 125 may obtain the image information by photographing the substrate G for each area of a predetermined size. In this case, the vision module 125 may include an area scan camera.

The vision module 125 may be attached to a bottom or side surface of the gantry unit 130 to obtain the image information of the substrate G onto which the substrate treatment liquid has been jetted. However, the current embodiment is not limited thereto. The vision module 125 may also be attached to a side surface of the inkjet head unit 140. At least one vision module 125 may be provided in the substrate treatment apparatus 100 and may be fixedly installed or movably installed.

The gantry unit 130 supports the inkjet head unit 140. The gantry unit 130 may be provided above the first stage 111 and the second stage 121 so that the inkjet head unit 140 can jet the substrate treatment liquid onto the substrate G.

The gantry unit 130 may be provided above the first stage 111 and the second stage 121 with the width direction (second direction 20) of the first stage 111 and the second stage 121 as its longitudinal direction. The gantry unit 130 may move along a first guide rail 170a and a second guide rail 170b in the longitudinal direction (first direction 10) of the first stage 111 and the second stage 121. The first guide rail 170a and the second guide rail 170b may be provided outside the first stage 111 and the second stage 121 along the longitudinal direction (first direction 10) of the first stage 111 and the second stage 121.

Although not illustrated in FIG. 1, the substrate treatment apparatus 100 may further include a gantry moving unit. The gantry moving unit slides the gantry unit 130 along the first guide rail 170a and the second guide rail 170b. The gantry moving unit may be installed inside the gantry unit 130.

The inkjet head unit 140 jets the substrate treatment liquid onto the substrate G in the form of droplets. The inkjet head unit 140 may be installed on a side or bottom surface of the gantry unit 130.

At least one inkjet head unit 140 may be installed on the gantry unit 130. When a plurality of inkjet head units 140 are installed on the gantry unit 130, they may be arranged in a line along the longitudinal direction (second direction 20) of the gantry unit 130. In addition, the inkjet head units 140 may operate independently or, conversely, may operate in a unified manner.

The inkjet head unit 140 may move along the longitudinal direction (second direction 20) of the gantry unit 130 so as to be positioned at a desired location on the substrate G. However, the current embodiment is not limited thereto. The inkjet head unit 140 may also move along a height direction (third direction 30) of the gantry unit 130 and rotate clockwise or counterclockwise.

The inkjet head unit 140 may also be fixed to the gantry unit 130. In this case, the gantry unit 130 may be movably provided.

Although not illustrated in FIG. 1, the substrate treatment apparatus 100 may further include an inkjet head moving unit. The inkjet head moving unit linearly moves or rotates the inkjet head unit 140.

The substrate treatment liquid providing unit 150 is a reservoir that provides the substrate treatment liquid to the inkjet head unit 140. The substrate treatment liquid providing unit 150 may be installed on the gantry unit 130 and may include a storage tank 151 and a pressure control module 152.

The storage tank 151 stores the substrate treatment liquid, and the pressure control module 152 controls the internal pressure of the storage tank 151. The storage tank 151 may supply an appropriate amount of substrate treatment liquid to the inkjet head unit 140 based on the pressure provided by the pressure control module 152.

The controller 160 controls the entire operation of each unit constituting the substrate treatment apparatus 100. The controller 160 may control, for example, the operation of the air holes 112 and the gripper of the process processing unit 110, the vision module 125 of the maintenance unit 120, the gantry unit 130, the inkjet head unit 140, and the pressure control module 152 of the substrate treatment liquid providing unit 150.

The controller 160 may include a process controller, a control program, an input module, an output module (or display module) and a memory module and may be implemented as a computer or server. Here, the process controller may include a microprocessor that executes a control function for each component constituting the substrate treatment apparatus 100, and the control program may execute various treatment operations of the substrate treatment apparatus 100 under the control of the process controller. The memory module stores programs, that is, treatment recipes for executing various treatment operations of the substrate treatment apparatus 100 according to various data and treatment conditions.

The controller 160 may also perform maintenance of the inkjet head unit 140. For example, the controller 160 may correct the jetting position of the substrate treatment liquid of each of a plurality of nozzles provided in the inkjet head unit 140 based on the measurement result of the maintenance unit 120 or may detect a defective nozzle (that is, a nozzle that does not jet the substrate treatment liquid) among the nozzles and control a cleaning operation to be performed on the defective nozzle.

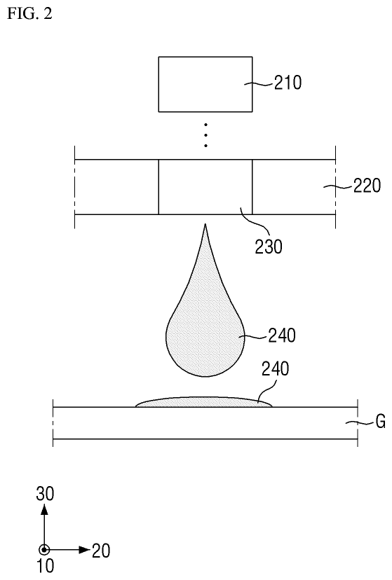

In the current embodiment, the substrate treatment apparatus 100 may be a piezoelectric based inkjet printing system. When the substrate treatment apparatus 100 is provided as such a system, a substrate treatment liquid 240 may be flown onto the substrate G in the form of droplets through a nozzle 230 of the inkjet head unit 140 according to a voltage applied to a piezoelectric element 210 as illustrated in FIG. 2. FIG. 2 is an example view for explaining a method of operating the substrate treatment apparatus 100 according to the embodiment of the present disclosure.

When the substrate treatment apparatus 100 is provided as a piezoelectric based inkjet printing system, the inkjet head unit 140 may include the piezoelectric element 210, a nozzle plate 220, and a plurality of nozzles 230. The nozzle plate 220 forms the body of the inkjet head unit 140. The nozzles 230 (e.g., 128 nozzles, 256 nozzles, etc.) may be provided in multiple rows and multiple columns at regular intervals in a lower portion of the nozzle plate 220, and the piezoelectric element 210 may be provided in the number corresponding to the number of nozzles 230 in the nozzle plate 220. The inkjet head unit 140 configured as described above may jet the substrate treatment liquid 240 onto the substrate G through each of the nozzles 230 according to the operation of the piezoelectric element 210.

The inkjet head unit 140 may independently control the amount of substrate treatment liquid 240 jetted through each nozzle 230 according to the voltage applied to the piezoelectric element 210.

The substrate treatment apparatus 100 may treat the substrate G through inkjet printing. In inkjet printing, a swath is performed, and a layer is printed to a desired thickness. To this end, the substrate treatment apparatus 100 performs printing while alternately moving forward and backward.

The substrate treatment apparatus 100 generates an image for printing based on nozzle information, i.e., a nozzle map of the inkjet head unit 140. In addition, the substrate treatment apparatus 100 generates an image by constructing a nozzle map such that a nozzle not jetting the substrate treatment liquid (i.e., a non-jetting nozzle) in the process of generating an image is compensated for by a nozzle of a next swath matched to the position of the non-jetting nozzle. Here, a swath refers to performing inkjet printing by scanning the substrate G from one end to the other end once.

However, if a non-jetting nozzle of a current swath and a non-jetting nozzle of a next swath overlap at the same position, compensation is impossible. In this case, an image is regenerated by increasing the number of scans in the process of generating an image. However, as described above, if the number of scans increases, the tact time of the entire equipment may increase.

In order to solve this problem, the present disclosure reconstructs a compensation nozzle map by processing nozzles in a specific area as unused nozzles among a plurality of nozzles installed in the inkjet head unit 140. More specifically, the controller 160 may reconstruct a compensation nozzle map by processing nozzles in a specific area as unused nozzles among all nozzles installed in the inkjet head unit 140 and shifting non-jetting compensation nozzles paired with each other. Then, printing may be performed based on the reconstructed compensation nozzle map. Accordingly, the above problem can be solved.

The features of the present disclosure described above will now be described in detail with reference to the drawings and the like.

The nozzles 230 installed in the inkjet head unit 140 jet the substrate treatment liquid 240 onto the substrate G while reciprocating between one end and the other end of the substrate G for substrate printing. The nozzles 230 may reciprocate between one end and the other end of the substrate G as the gantry moving unit (not illustrated) moves the gantry unit 130 and may also reciprocate between one end and the other end of the substrate G as the inkjet head moving unit (not illustrated) moves the inkjet head unit 140 on the gantry unit 130.

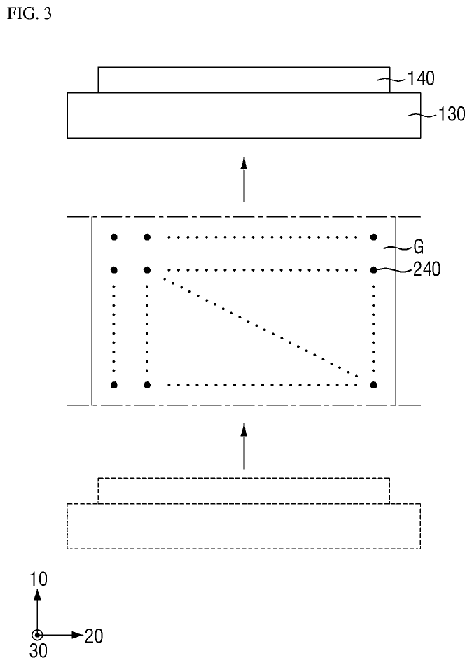

For example, as illustrated in FIG. 3, the inkjet head unit 140 may move forward from one end of the substrate G to the other end according to the forward movement of the gantry unit 130. In this case, the nozzles 230 installed in the inkjet head unit 140 may jet the substrate treatment liquid 240 onto the substrate G at regular intervals.

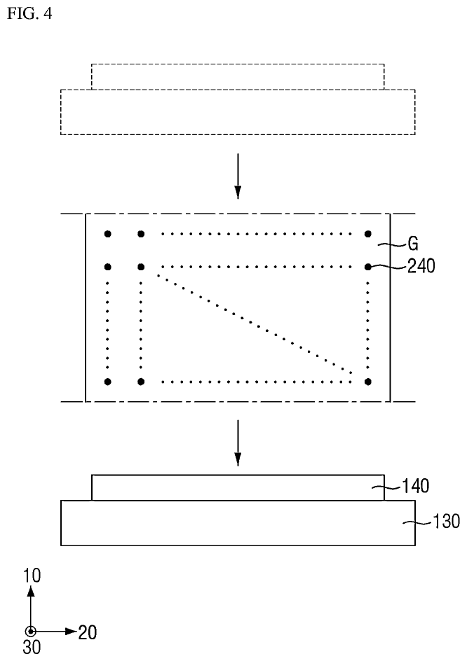

In addition, as illustrated in FIG. 4, the inkjet head unit 140 may move backward from the other end of the substrate G to the one end according to the backward movement of the gantry unit 130. In this case, the nozzles 230 installed in the inkjet head unit 140 may jet the substrate treatment liquid 240 onto the substrate G at regular intervals.

FIG. 3 is an example view illustrating an operation of jetting the substrate treatment liquid 240 onto the substrate G by moving the inkjet head unit 140 forward for substrate printing. FIG. 4 is an example view illustrating an operation of jetting the substrate treatment liquid 240 onto the substrate G by moving the inkjet head unit 140 backward for substrate printing. In the following description, a case where the inkjet head unit 140 includes ten nozzles 310a, 310b, . . . , 310i and 310j will be described as an example. However, the current embodiment is not limited to the number of nozzles 230 installed in the inkjet head unit 140.

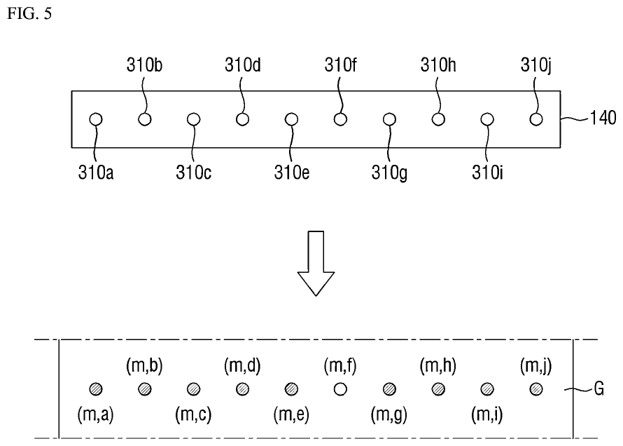

In the case of a first swath, for example, when the inkjet head unit 140 moves forward from one end of the substrate G to the other end, first through tenth nozzles 310a through 310j may jet the substrate treatment liquid 240 onto the substrate G. Here, any one of the first through tenth nozzles 310a through 310j may not jet the substrate treatment liquid 240 at an (m, f) position as illustrated in FIG. 5.

Next, in the case of a second swath, for example, when the inkjet head unit 140 moves backward from the other end of the substrate G to the one end, any one of the first through tenth nozzles 310a through 310j may not jet the substrate treatment liquid 240 at the (m, f) position, as in the case of the first swath. FIG. 5 is a first example view for explaining a non-jetting nozzle compensation method of the controller 160 constituting the substrate treatment apparatus 100.

When a phenomenon in which the substrate treatment liquid 240 is not jetted occurs in the first swath, the controller 160 may reconstruct a nozzle map. Therefore, a nozzle that jets the substrate treatment liquid 240 at the (m, f) position in the first swath and a nozzle that jets the substrate treatment liquid 240 at the (m, f) position in the second swath may be different from each other. However, even if the nozzles are changed, the phenomenon in which the substrate treatment liquid 240 is not jetted can occur again at the same position.

On the other hand, if the controller 160 does not reconstruct the nozzle map, a nozzle that jets the substrate treatment liquid 240 at the (m, f) position in the first swath and a nozzle that jets the substrate treatment liquid 240 at the (m, f) position in the second swath may be the same.

In this case, the controller 160 may reconstruct a compensation nozzle map by processing some nozzles that operate normally among all nozzles as unused nozzles and may proceed with a next swath. Due to this operating method of the controller 160 in the current embodiment, the number of scans may not be increased, and an increase in tact time can be prevented.

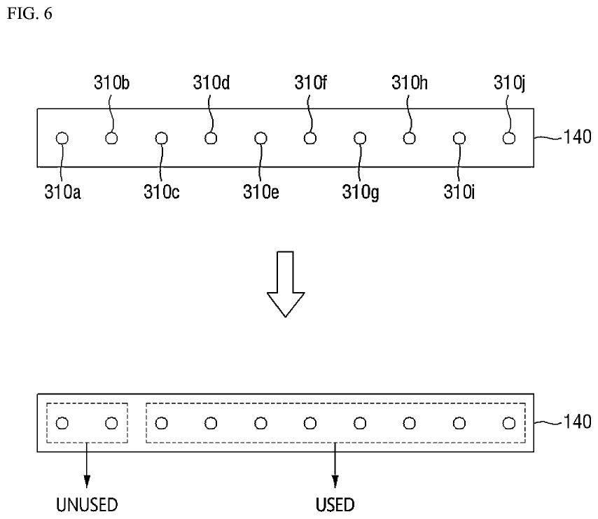

For example, the controller 160 may process the first two nozzles or the first two or more nozzles (e.g., the first four nozzles) among all nozzles as unused nozzles. Here, the first two nozzles or the first two or more nozzles may refer to two nozzles or two or more nozzles located at either end in an arrangement structure. Alternatively, the first two nozzles or the first two or more nozzles may refer to two nozzles or two or more nozzles located first in a jetting order. As illustrated in FIG. 6, the controller 160 may process the first nozzle 310a and the second nozzle 310b as unused nozzles among the first through tenth nozzles 310a through 310j. FIG. 6 is a first example view for explaining an unused nozzle determination method of the controller 160 constituting the substrate treatment apparatus 100.

In addition, the controller 160 may process the last two nozzles or the last two or more nozzles (e.g., the last four nozzles) among all nozzles as unused nozzles.

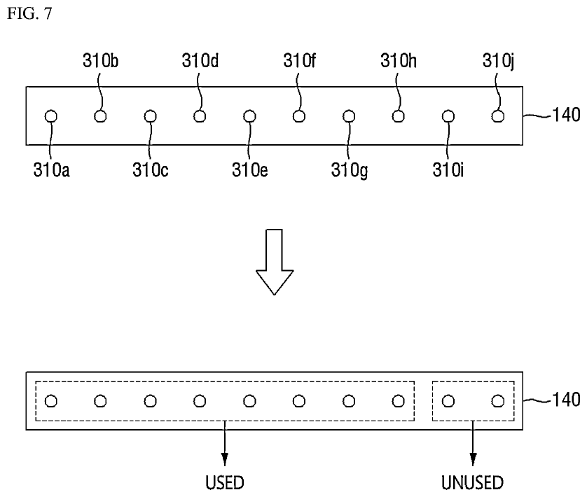

Here, the last two nozzles or the last two or more nozzles may refer to two nozzles or two or more nozzles located at the other end in the arrangement structure. Alternatively, the last two nozzles or the last two or more nozzles may refer to two nozzles or two or more nozzles located last in the jetting order. As illustrated in FIG. 7, the controller 160 may process the ninth nozzle 310i and the tenth nozzle 310j as unused nozzles among the first through tenth nozzles 310a through 310j. FIG. 7 is a second example view for explaining an unused nozzle determination method of the controller 160 constituting the substrate treatment apparatus 100.

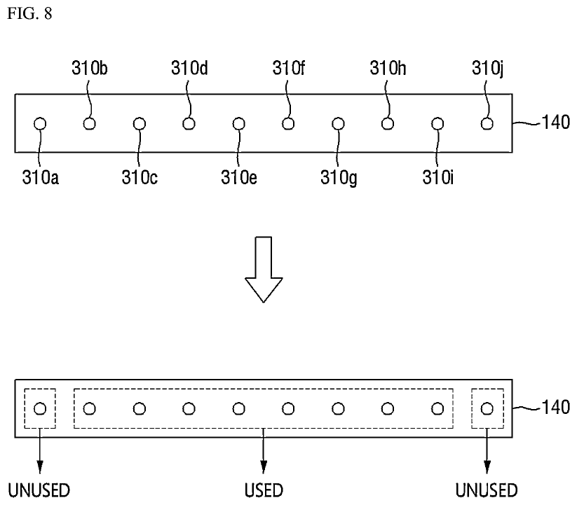

In addition, the controller 160 may process the first one nozzle and the last one nozzle or the first one or more nozzles and the last one or more nozzles (e.g., the first two nozzles and the last two nozzles or the first three nozzles and the last one nozzle) among all nozzles as unused nozzles. As illustrated in FIG. 8, the controller 160 may process the first nozzle 310a and the tenth nozzle 310j as unused nozzles among the first through tenth nozzles 310a through 310j. FIG. 8 is a third example view for explaining an unused nozzle determination method of the controller 160 constituting the substrate treatment apparatus 100.

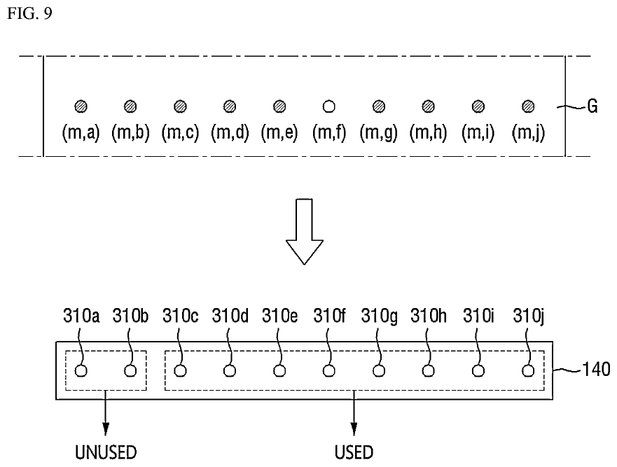

The controller 160 may determine the number of nozzles to be processed as unused nozzles according to the number of non-jetting nozzles. The controller 160 may determine the number of nozzles to be processed as unused nozzles such that the number of nozzles to be processed as unused nozzles is greater than the number of non-jetting nozzles. For example, when the substrate treatment liquid 240 is not jetted at the (m, f) position among (m, a) through (m, j) positions, the controller 160 may process the first nozzle 310a and the second nozzle 310b as unused nozzles among the first through tenth nozzles 310a through 310j as illustrated in FIG. 9. Alternatively, the controller 160 may process the ninth nozzle 310i and the tenth nozzle 310j as unused nozzles among the first through tenth nozzles 310a through 310j. Alternatively, the controller 160 may process the first nozzle 310a and the tenth nozzle 310j as unused nozzles among the first through tenth nozzles 310a through 310j. FIG. 9 is a fourth example view for explaining an unused nozzle determination method of the controller 160 constituting the substrate treatment apparatus 100.

The controller 160 may also determine the number of nozzles to be processed as unused nozzles such that the number of non-jetting nozzles and the number of nozzles to be processed as unused nozzles are equal.

The controller 160 may determine the number of nozzles to be processed as unused nozzles according to the number of non-jetting nozzles, but may process some nozzles among all nozzles as unused nozzles. For example, when the substrate treatment liquid 240 is not jetted at the (m, f) position among the (m, a) through (m, j) positions, the controller 160 may select at least two nozzles from among the first through tenth nozzles 310a through 310j and process the selected nozzles as unused nozzles or may select up to eight nozzles and process the selected nozzles as unused nozzles. Preferably, the controller 160 may determine the number of nozzles to be processed as unused nozzles to be greater than the number of non-jetting nozzles by one.

The controller 160 may determine nozzles to be processed as unused nozzles among normally operating nozzles.

When some nozzles among all nozzles are processed as unused nozzles, the controller 160 may shift substrate treatment liquid jetting positions of all nozzles except for the nozzles processed as unused nozzles.

For example, it may be assumed that the substrate treatment liquid 240 was not jetted at the (m, f) position among the (m, a) through (m, j) positions in the first swath, that the sixth nozzle 310f among the first through tenth nozzles 310a through 310j is a non-jetting nozzle, and that the sixth nozzle 310f is scheduled to jet the substrate treatment liquid 240 at the (m, f) position in the second swath.

In this case, the controller 160 may process the first two normally operating nozzles, that is, the first nozzle 310a and the second nozzle 310b as unused nozzles among the first through tenth nozzles 310a through 310j.

Alternatively, the controller 160 may process the last two normally operating nozzles, that is, the ninth nozzle 310i and the tenth nozzle 310j as unused nozzles among the first through tenth nozzles 310a through 310j.

Alternatively, the controller 160 may process the first one normally operating nozzle and the last one normally operating nozzle, that is, the first nozzle 310a and the tenth nozzle 310j as unused nozzles among the first through tenth nozzles 310a through 310j.

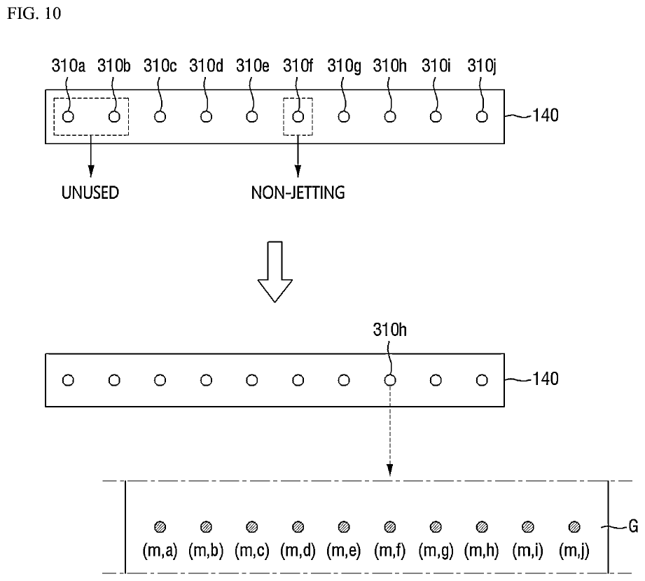

When the first two nozzles, that is, the first nozzle 310a and the second nozzle 310b are processed as used nozzles, the controller 160 may control the third nozzle 310c to jet the substrate treatment liquid 240 at the (m, a) position as illustrated in FIG. 10. In this case, the eighth nozzle 310h jets the substrate treatment liquid 240 at the (m, f) position. Since the eighth nozzle 310h is a nozzle that can normally jet the substrate treatment liquid 240, it is possible to solve the problem of the substrate treatment liquid 240 not being jetted again at the (m, f) position in the second swath. FIG. 10 is a second example view for explaining a non-jetting nozzle compensation method of the controller 160 constituting the substrate treatment apparatus 100.

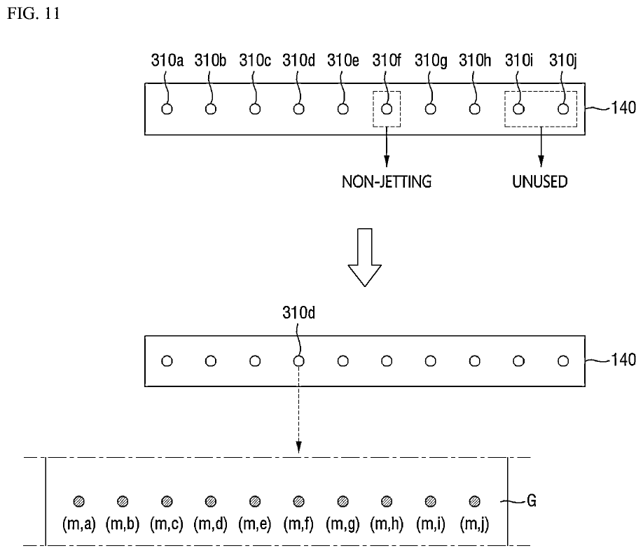

Similarly, when the last two nozzles, that is, the ninth nozzle 310i and the tenth nozzle 310j are processed as unused nozzles, the controller 160 may control the eighth nozzle 310h to jet the substrate treatment liquid 240 at the (m, j) position as illustrated in FIG. 11. In this case, the fourth nozzle 310d jets the substrate treatment liquid 240 at the (m, f) position. Since the fourth nozzle 310d is a nozzle that can normally jet the substrate treatment liquid 240, it is possible to solve the problem of the substrate treatment liquid 240 not being jetted again at the (m, f) position in the second swath. FIG. 11 is a third example view for explaining a non-jetting nozzle compensation method of the controller 160 constituting the substrate treatment apparatus 100.

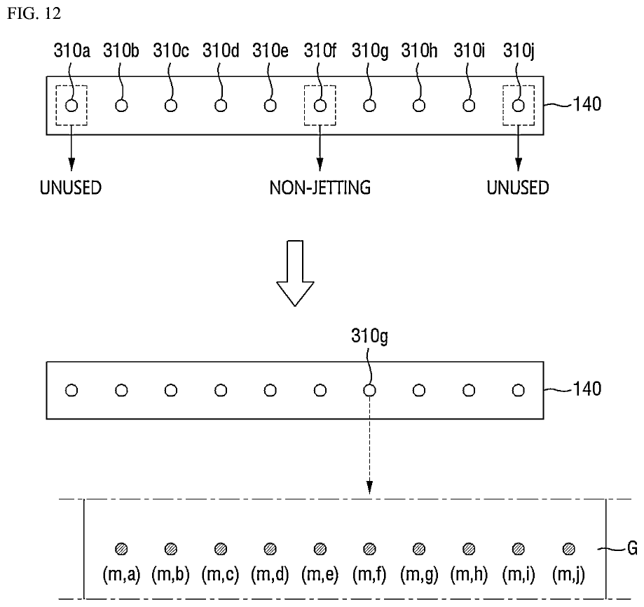

In addition, when the first one nozzle and the last one nozzle, that is, the first nozzle 310a and the tenth nozzle 310j are processed as unused nozzles, the controller 160 may control the second nozzle 310b to jet the substrate treatment liquid 240 at the (m, a) position as illustrated in FIG. 12. In this case, the seventh nozzle 310g jets the substrate treatment liquid 240 at the (m, f) position. Since the seventh nozzle 310g is a nozzle that can normally jet the substrate treatment liquid 240, it is possible to solve the problem of the substrate treatment liquid 240 not being jetted again at the (m, f) position in the second swatch. FIG. 12 is a fourth example view for explaining a non-jetting nozzle compensation method of the controller 160 constituting the substrate treatment apparatus 100.

Alternatively, the controller 160 may control the ninth nozzle 310i to jet the substrate treatment liquid 240 at the (m, j) position. In this case, the fifth nozzle 310e jets the substrate treatment liquid 240 at the (m, f) position. Since the fifth nozzle 310e is a nozzle that can normally jet the substrate treatment liquid 240, it is possible to solve the problem of the substrate treatment liquid 240 not being jetted again at the (m, f) position in the second swatch.

The present disclosure is designed to improve a non-jetting compensation method of inkjet equipment. In the present disclosure, a compensation nozzle map is reconstructed by processing nozzles in a specific area among all nozzles as unused nozzles and shifting non-jetting compensation nozzles paired with each other. Then, printing is performed based on the reconstructed compensation nozzle map. Accordingly, a non-jetting problem can be compensated for. Here, the nozzles in the specific area may be, for example, the last two, four or more nozzles among all nozzles. Alternatively, the nozzles in the specific area may be the first two, four or more nozzles among all nozzles. Alternatively, the nozzles in the specific area may be the first one nozzle and the last one nozzle or the first several nozzles and the last several nozzles among all nozzles.

When a non-jetting nozzle of a current swath and a non-jetting nozzle of a next swath overlap at the same position in the process of generating an image for printing, nozzles in a specific area among all nozzles are processed as unused nozzles, instead of regenerating an image by increasing the number of scans.

If a nozzle map is constructed such that nozzles in a specific area are processed as unused nozzles, an area where the non-jetting nozzle of the current swath and the non-jetting nozzle of the next swath overlap is shifted by a distance corresponding to the specific area having the nozzles processed as unused nozzles.

If the nozzle map is configured such that nozzles in a specific area are processed as unused nozzles, the number of scans may not be increased, and desired printing may be performed through the same number of swaths as before.

However, if nozzles in a specific area are thoughtlessly processed as unused nozzles, the total number of printing swaths may increase. Therefore, the number of unused nozzles in a specific area is limited according to the area where the non-jetting nozzle of the current swath and the non-jetting nozzle of the next swath overlap.

According to the present disclosure, when the non-jetting nozzle of the current swath and the non-jetting nozzle of the next swath overlap at the same position, non-jetting can be compensated for without an increase in the number of scans. Since the conventional method (that is, increasing the number of scans) can be improved, it is possible to compensate for non-jetting nozzles without increasing the tact time.

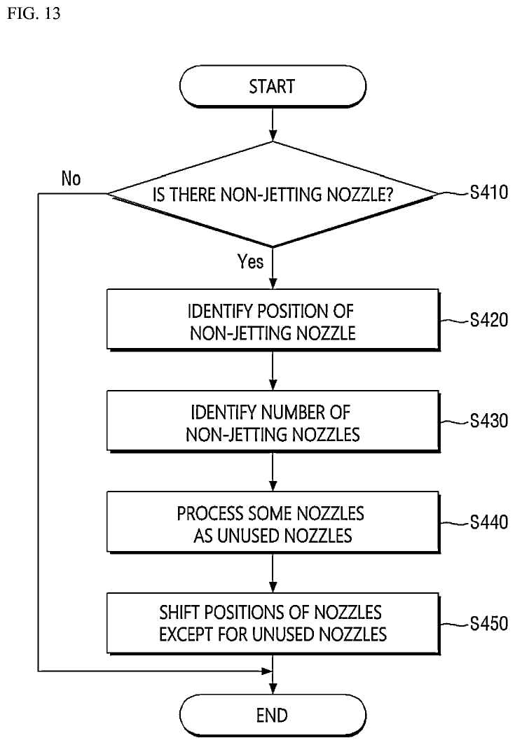

Next, a non-jetting nozzle compensation method of the controller 160 will be described. FIG. 13 is a flowchart sequentially illustrating a method of operating the controller 160 constituting the substrate treatment apparatus 100. The following description is given with reference to FIG. 13.

First, the controller 160 determines whether there is a non-jetting nozzle that has not jetted the substrate treatment liquid 240, that is, an abnormal nozzle among the nozzles 230 of the inkjet head unit 140 (operation S410).

The determination of an abnormal nozzle by the controller 160 may be performed in detail in the following order.

First, the inkjet head unit 140 jets the substrate treatment liquid 240 onto the substrate G to treat the substrate G.

When the inkjet head unit 140 finishes jetting the substrate treatment liquid 240, a droplet inspection unit obtains image information by photographing the surface of the substrate G under the control of the controller 160. To this end, the droplet inspection unit may include a camera module and may also utilize the vision module 125 constituting the maintenance unit 120.

The droplet inspection unit may also obtain image information by photographing the surface of the substrate G in real time while the inkjet head unit 140 is jetting the substrate treatment liquid 240 onto the substrate G.

When the image information of the surface of the substrate G is obtained by the droplet inspection unit, the controller 160 determines whether there is an area of the substrate G onto which the substrate treatment liquid 240 has not been jetted based on the image information.

Here, if it is determined that there is an area of the substrate G onto which the substrate treatment liquid 240 has not been jetted, the controller 160 determines that there is a non-jetting nozzle, that is, an abnormal nozzle that has not jetted the substrate treatment liquid 240 among the nozzles 230. On the other hand, if it is determined that there is no area of the substrate G onto which the substrate treatment liquid 240 has not been jetted, the controller 160 determines that there is no non-jetting nozzle, that is, no abnormal nozzle that has not jetted the substrate treatment liquid 240 among the nozzles 230.

If it is determined that there is a non-jetting nozzle among the nozzles 230, the controller 160 identifies which nozzle is the non-jetting nozzle that has not jetted the substrate treatment liquid 240 based on a nozzle map in a current swath (operation S420). Here, the nozzle map refers to a map in which each nozzle and the jetting position of each nozzle are mapped for each swath, and the controller 160 may construct the nozzle map before performing substrate printing for each swath.

In addition, the controller 160 identifies the number of non-jetting nozzles (operation S430).

Next, the controller 160 processes some of the nozzles (i.e., normal nozzles that normally jet the substrate treatment liquid 240) excluding the non-jetting nozzles from all nozzles as unused nozzles (operation S440). The controller 160 may determine which nozzle to process as an unused nozzle based on the position and number of non-jetting nozzles. For example, when the second nozzle 310b is identified as an abnormal nozzle among the first through tenth nozzles 310a through 310j, the controller 160 may process the ninth nozzle 310i and the tenth nozzle 310j as unused nozzles. Alternatively, the controller 160 may process the first nozzle 310a and the tenth nozzle 310j as unused nozzles. The method of processing nozzles in a specific area as unused nozzles has been described above with reference to FIGS. 6 through 9, and thus a detailed description thereof is omitted here.

When some nozzles among all nozzles are processed as unused nozzles, the controller 160 shifts substrate treatment liquid jetting positions of all normally operating nozzles except for the nozzles processed as unused nozzles (operation S450). The method of compensating for non-jetting nozzles has been described above with reference to FIGS. through 12, and thus a detailed description thereof is omitted here.

Next, the substrate treatment liquid 240 is jetted onto the substrate G using the nozzles 230 of the inkjet head unit 140 whose positions have been adjusted. Since non-jetting nozzles are compensated for through operations S410 through S450, the number of scans may not be increased, thereby preventing an increase in tact time.

The non-jetting nozzle compensation method of the controller 160 described above may be performed in a setting operation before the substrate G is printed.

While the present disclosure has been particularly illustrated and described with reference to exemplary embodiments thereof, it will be understood by those of ordinary skill in the art that various changes in form and detail may be made therein without departing from the concept and scope of the present disclosure as defined by the following claims. The exemplary embodiments should be considered in a descriptive sense only and not for purposes of limitation.

What is claimed is:

1. A substrate treatment apparatus comprising:
a process processing unit supporting a substrate while the substrate is being treated;
an inkjet head unit comprising a plurality of nozzles and jetting a substrate treatment liquid onto the substrate to treat the substrate;
a gantry unit moving the inkjet head unit on the substrate; and
a controller controlling the nozzles,
wherein the controller compensates for an abnormal nozzle by not using normal nozzles.

2. The apparatus of claim 1, wherein when it is determined that there is the abnormal nozzle among the nozzles in a previous swath, the controller compensates for the abnormal nozzle by not using the normal nozzles.

3. The apparatus of claim 1, wherein when a jetting position of the abnormal nozzle is the same in substrate printing for each of successive swaths, the controller compensates for the abnormal nozzle by not using the normal nozzles.

4. The apparatus of claim 1, wherein the controller processes a plurality of nozzles located on one side in an arrangement structure among the nozzles as unused nozzles or processes nozzles respectively located on both sides as unused nozzles.

5. The apparatus of claim 1, wherein the controller processes a plurality of nozzles located first among the nozzles as unused nozzles, processes a plurality of nozzles located last as unused nozzles, or processes a nozzle located first and a nozzle located last as unused nozzles.

6. The apparatus of claim 5, wherein the nozzle located first and the nozzle located last are determined by a jetting order of the substrate treatment liquid.

7. The apparatus of claim 1, wherein the controller processes some of the nozzles as unused nozzles.

8. The apparatus of claim 1, wherein the controller determines the number of unused normal nozzles according to the number of abnormal nozzles.

9. The apparatus of claim 8, wherein the number of unused normal nozzles is greater than the number of abnormal nozzles.

10. The apparatus of claim 1, wherein the controller compensates for the abnormal nozzle by shifting all nozzles except for the unused nozzles.

11. The apparatus of claim 10, wherein the controller determines a direction in which the all nozzles are to be shifted according to the positions of the unused nozzles.

12. The apparatus of claim 1, wherein the controller constructs a nozzle map by mapping a jetting position of each nozzle for each swath and identifies the position of the abnormal nozzle based on the nozzle map.

13. The apparatus of claim 12, wherein the controller determines unused nozzles based on the position of the abnormal nozzle.

14. The apparatus of claim 13, wherein the controller further identifies the number of abnormal nozzles based on the nozzle map and considers the number of abnormal nozzles when determining the unused nozzles.

15. A substrate treatment apparatus comprising:
a process processing unit supporting a substrate while the substrate is being treated;
an inkjet head unit comprising a plurality of nozzles and jetting a substrate treatment liquid onto the substrate to treat the substrate;
a gantry unit moving the inkjet head unit on the substrate; and
a controller controlling the nozzles,
wherein the controller compensates for an abnormal nozzle by not using normal nozzles when a jetting position of the abnormal nozzle is the same in substrate printing for each of successive swaths, the controller processes a plurality of nozzles located first in a jetting order among the nozzles as unused nozzles, processes a plurality of nozzles located last as unused nozzles, or processes a nozzle located first and a nozzle located last as unused nozzles, the controller compensates for the abnormal nozzle by shifting all nozzles except for the unused nozzles, and the controller determines the number of unused normal nozzles according to the number of abnormal nozzles.

16. A substrate treatment method comprising:
determining whether there is an abnormal nozzle among a plurality of nozzles;
identifying the position and number of abnormal nozzles if it is determined that there is the abnormal nozzle;
processing some of normal nozzles as unused nozzles;
compensating for the abnormal nozzle using all nozzles except for the unused nozzles; and
printing a substrate using the all nozzles whose jetting positions have been adjusted.

17. The method of claim 16, wherein in the compensating for the abnormal nozzle, the abnormal nozzle is compensated for by adjusting the jetting positions of the all nozzles except for the unused nozzles.

18. The method of claim 16, being performed when a jetting position of the abnormal nozzle is the same in substrate printing for each of successive swaths.

19. The method of claim 16, wherein in the processing of some of the nozzles as the unused nozzles, a plurality of nozzles located first in a jetting order among the nozzles are processed as unused nozzles, a plurality of nozzles located last are processed as unused nozzles, or a nozzle located first and a nozzle located last are processed as unused nozzles.

20. The method of claim 16, wherein in the processing of some of the nozzles as the unused nozzles, the number of unused normal nozzles is determined according to the number of abnormal nozzles.
